(19) United States
(12) Patent Application Publication
(10) Pub. No.: US 2018/0242464 A1
(43) Pub. Date: Aug. 23, 2018

(54) MULTILAYER SUBSTRATE AND METHOD FOR MANUFACTURING THE SAME

(71) Applicant: DENSO CORPORATION, Kariya-city, Aichi-pref. (JP)

(72) Inventors: Kenichiro HASEGAWA, Kariya-city, Aichi-pref. (JP); Tomohiro YOKOCHI, Kariya-city, Aichi-pref. (JP); Yasunori KASAMA, Kariya-city, Aichi-pref. (JP)

(73) Assignee: DENSO CORPORATION, Kariya-city, Aichi-pref. (JP)

(21) Appl. No.: 15/756,745

(22) PCT Filed: Aug. 8, 2016
(86) PCT No.: PCT/JP2016/073348

§ 371 Date: Mar. 1, 2018

(30) Foreign Application Priority Data
Sep. 1, 2015 (JP) 2015-172166

(51) Int. Cl. H05K 3/46; H05K 1/11; H05K 1/02

(52) U.S. Cl. CPC H05K 3/462; H05K 3/4623; H05K 1/113; H05K 3/0014; H05K 2201/09709; H05K 2201/09454; H05K 2201/09827; H05K 1/0271

(57) ABSTRACT

Before a laminated body is subjected to hot pressing, at least two or more land electrodes are displaced from each other as viewed in the lamination direction, whereby at least two or more gaps disposed in the lamination direction are displaced from each other as viewed in the lamination direction. The hot pressing on the laminated body causes resin materials that compose resin films to flow and fill the gaps in the laminated body. Consequently, the planarity of a multilayer substrate can be improved to a greater extent than in a case where a plurality of gaps disposed in the lamination direction is located at the same position as viewed in the lamination direction.

### TECHNICAL FIELD

The present invention relates to a multilayer substrate and a method for manufacturing the same.

### BACKGROUND ART

A conventional method for manufacturing a multilayer substrate includes laminating a plurality of resin films to form a laminated body and subjecting the laminated body to hot pressing (for example, see PTL 1). Specifically, each of the plurality of resin films has land electrodes formed on the surface thereof and via-forming materials filled into through holes. The hot pressing is performed at a temperature at which the resin films are softened. The hot pressing causes the resin films to be softened to flow and fill the gaps between adjacent resin films, so that the adjacent resin films are bonded to each other through thermal fusion bonding.

### CITATION LIST

### Patent Literature

[PTL 1]

JP 2007-53393 A

### SUMMARY OF THE INVENTION

### Technical Problem

Conventionally, the land electrodes formed on the respective resin films have the same planar pattern shape. The land electrodes are also arranged at the same position in the laminated body as viewed in the lamination direction of the resin films. In addition, vias in the respective resin films are arranged such that the centers of the vias are aligned with the centers of the land electrodes. In other words, the vias in the laminated body are linearly arranged in the lamination direction of the plurality of resin films.

In the laminated body which has not been subjected to the hot pressing, there is a gap between adjacent resin films and in particular between land electrodes on the surface of one resin film. In other words, there is a gap in a region free from land electrodes. Therefore, the multilayer substrate subjected to the hot pressing is thinner in the region free from land electrodes than in the region provided with land electrodes. This is why the planarity of the board surface is deteriorated after the multilayer substrate is subjected to the hot pressing.

In consideration of the above-mentioned points, an object of the present invention is to provide a multilayer substrate with improved planarity through hot pressing and a method for manufacturing the same.

### Solution to the Problem

In order to achieve the above-mentioned object, a first aspect is a method for manufacturing a multilayer substrate, the method including: a preparation process of preparing a plurality of film-like insulating substrates including at least a resin material, the insulating substrates each including: a land electrode formed on a surface of the insulating substrate and having a predetermined planar shape; and an interlayer connection material filled into a through hole penetrating the insulating substrate in a thickness direction and linked to the land electrode; a lamination process of laminating the plurality of insulating substrates to form a laminated body including: a continuous structure including a plurality of the land electrodes and a plurality of the interlayer connection materials continuously arranged in a lamination direction of the insulating substrates; and a gap generated in a region free from the land electrodes between the laminated insulating substrates, a plurality of the gaps being present in the lamination direction; and a heating pressing process of heating and pressing the laminated body in the lamination direction to cause the plurality of insulating substrates to flow and fill the gaps, and the lamination process includes forming the laminated body in which at least two or more of the land electrodes that configure the continuous structure are displaced from each other as viewed in the lamination direction, and at least two or more of the gaps present in the lamination direction are displaced from each other as viewed in the lamination direction.

In the present aspect, before the laminated body is subjected to the heating pressing process, at least two or more land electrodes are displaced from each other, whereby at least two or more gaps disposed in the lamination direction are displaced from each other. Consequently, the thickness of the multilayer substrate subjected to the heating pressing process can be much more uniform than that in a case where all of a plurality of gaps disposed in the lamination direction are located at the same position as viewed in the lamination direction. Therefore, according to the present invention, the planarity of the multilayer substrate can be improved.

A second aspect is a multilayer substrate including: a plurality of film-like insulating substrates including at least a resin material and laminated; a plurality of land electrodes arranged on a surface of each of the plurality of insulating substrates and having a predetermined planar shape; and a plurality of interlayer connection materials provided in each of the plurality of insulating substrates and connected to the land electrodes, the plurality of land electrodes and the plurality of interlayer connection materials are continuously arranged in a lamination direction of the insulating substrates to form a continuous structure, and at least two or more of the land electrodes that configure the continuous structure are displaced from each other as viewed in the lamination direction.

In the present aspect, at least two or more land electrodes that configure the continuous structure are displaced from each other as viewed in the lamination direction. Consequently, in the case of laminating a plurality of insulating substrates provided with land electrodes on the surfaces thereof to form a laminated body and heating and pressing the laminated body to manufacture a multilayer substrate, the thickness of the multilayer substrate can be made as uniform as possible. Therefore, according to the present invention, the planarity of the multilayer substrate can be improved.

The reference sign in brackets for each means described in the claims is an example indicating the correspondence between the means and a specific means described in the following embodiments.

### BRIEF DESCRIPTION OF DRAWINGS

FIG. 1 is a cross-sectional view of a multilayer substrate according to a first embodiment.

FIG. 2A is a cross-sectional view illustrating a part of manufacturing process for the multilayer substrate according to the first embodiment.

FIG. 2B is a cross-sectional view illustrating a part of manufacturing process for the multilayer substrate according to the first embodiment.

FIG. 2C is a cross-sectional view illustrating a part of manufacturing process for the multilayer substrate according to the first embodiment.

FIG. 3A is a cross-sectional view illustrating a part of manufacturing process for a multilayer substrate according to Comparative Example 1.

FIG. 3B is a cross-sectional view illustrating a part of manufacturing process for the multilayer substrate according to Comparative Example 1.

FIG. 4A is a cross-sectional view of the multilayer substrate according to Comparative Example 1 at room temperatures.

FIG. 4B is a cross-sectional view of the multilayer substrate according to Comparative Example 1 at high temperatures.

FIG. 4C is a cross-sectional view of the multilayer substrate according to Comparative Example 1 at low temperatures.

FIG. 5 is a cross-sectional view of a multilayer substrate according to a second embodiment.

FIG. 6 is a cross-sectional view of a multilayer substrate according to a third embodiment.

FIG. 7 is a cross-sectional view illustrating a part of manufacturing process for the multilayer substrate according to the third embodiment.

FIG. 8 is a cross-sectional view of a multilayer substrate according to Comparative Example 2.

FIG. 9A is a cross-sectional view illustrating a part of manufacturing process for a multilayer substrate according to a fourth embodiment.

FIG. 9B is a cross-sectional view illustrating a part of manufacturing process for the multilayer substrate according to the fourth embodiment.

FIG. 10 is a plan view of a multilayer substrate according to a fifth embodiment.

FIG. 11 is a cross-sectional view of the multilayer substrate according to the fifth embodiment.

FIG. 12 is a perspective view of the multilayer substrate according to the fifth embodiment.

FIG. 13 is a view illustrating a plurality of land electrodes of FIG. 11 projected onto the same plane.

FIG. 14 is a view illustrating a plurality of vias of FIG. 11 on the same plane.

FIG. 15 is a cross-sectional view illustrating a part of manufacturing process for the multilayer substrate according to the fifth embodiment.

FIG. 16 is a plan view of a multilayer substrate according to a sixth embodiment.

FIG. 17 is a cross-sectional view of the multilayer substrate according to the sixth embodiment.

FIG. 18 is a cross-sectional view illustrating a part of manufacturing process for the multilayer substrate according to the sixth embodiment.

### DESCRIPTION OF EMBODIMENTS

Hereinafter, embodiments of the present invention will be described based on the drawings. In the following description of the embodiments, components identical or equivalent to one another are denoted by the same reference signs.

### First Embodiment

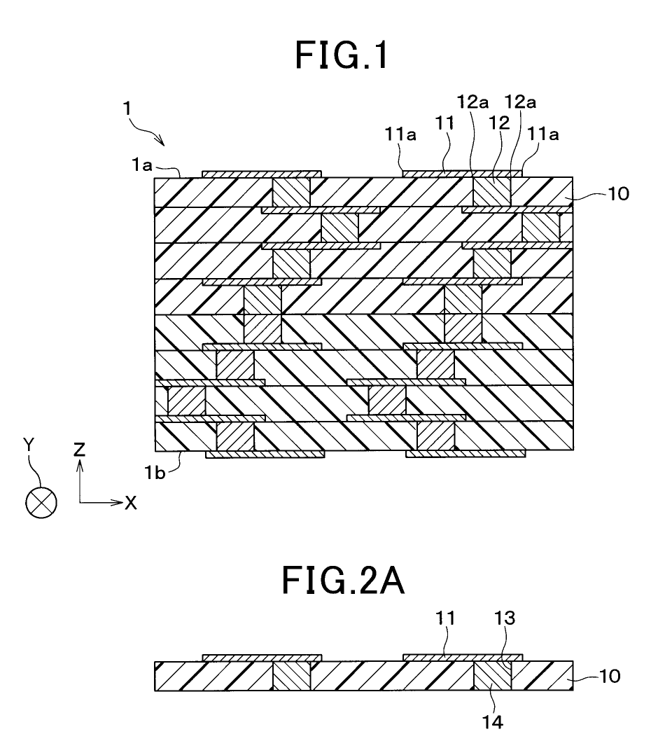

As illustrated in FIG. 1, a multilayer substrate 1 according to the present embodiment includes a plurality of laminated resin films 10. The multilayer substrate 1 has a first surface la which is a surface on one side in the lamination direction and a second surface 1b which is a surface opposite to the first surface lb. In the multilayer substrate 1, a plurality of land electrodes 11 is arranged in the lamination direction of the resin films 10. The land electrodes 11 are arranged on the first surface la, on the second surface 1b, and between the resin films 10 of the multilayer substrate 1. The plurality of land electrodes 11 is electrically connected to one another through vias 12 provided in the resin films 10. The land electrodes 11 and the vias 12 are alternately connected in the thickness direction of the multilayer substrate 1, that is, the lamination direction of the plurality of resin films 10. The Z direction in FIG. 1 is the thickness direction of the multilayer substrate 1. The land electrodes 11 and the vias 12 configure the wiring in the thickness direction of the multilayer substrate 1.

Each resin film 10 is a film-like insulating substrate. Each resin film 10 is made of a thermoplastic resin. The resin films 10 are bonded to one another. Each land electrode 11 is made of metal foil such as copper foil. The planar shape of each land electrode 11 is the same circular shape. Each via 12 is an interlayer connection material that connects the land electrodes located on both sides of the resin film 10. Each via 12 is made of sintered metal powder. The planar shape of each via 12 is the same circular shape.

The plurality of land electrodes 11 and the plurality of vias 12 are electrically connected in the thickness direction of the multilayer substrate such that one land electrode 11 is displaced from another land electrode 11 and one via 12 is displaced from another via 12. As used herein, the sentence “two land electrodes 11 are displaced from each other” means that the positions of opposite ends 11a of one land electrode 11 are different from those of the other land electrode 11 in the direction along the surface of the multilayer substrate 1. Similarly, the sentence “two vias 12 are displaced from each other” means that the positions of opposite ends 12a of one via 12 are different from those of the other via 12 in the direction along the surface of the multilayer substrate 1.

In the present embodiment, the plurality of land electrodes 11 is displaced from one another and the plurality of vias 12 is displaced from one another in the X direction. In the Y direction, the plurality of land electrodes 11 is arranged at the same position and the plurality of vias 12 is arranged at the same position. The X direction is one direction along the surface of the multilayer substrate 1. The Y direction is a direction along the surface of the multilayer substrate 1 and vertical to the X direction.

Next, a method for manufacturing the multilayer substrate 1 according to the present embodiment will be described.

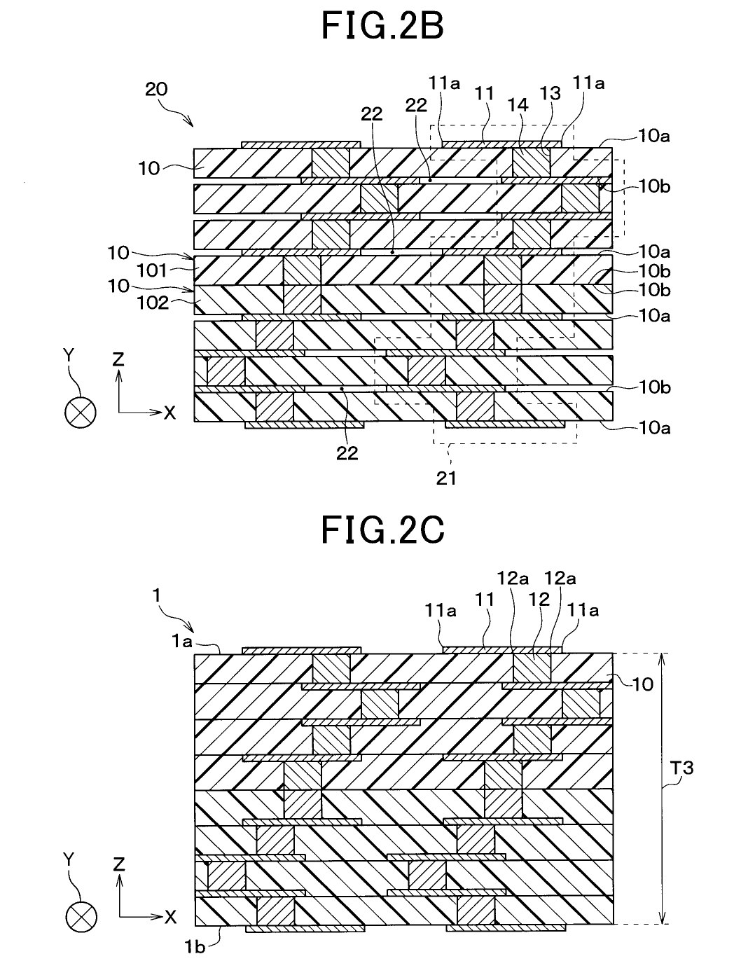

First, as illustrated in FIG. 2A, a preparation process for preparing the plurality of resin films 10 provided with the land electrodes 11 and the like is performed. More specifically, metal foil is provided on one surface of each resin film 10 and patterned. Consequently, the land electrodes 11 are formed only on one surface of each resin film 10. After that, via holes 13 are formed in each resin film 10 using laser processing or drill processing. The via hole 13 is a through hole penetrating from one surface to the other surface of the resin film 10 in the thickness direction of the resin film 10. The via hole 13 does not penetrate the land electrode 11. In other words, the via hole 13 is a bottomed hole covered by the land electrode 11. The via hole 13 is formed at a position overlapping the land electrode 11 as viewed in the thickness direction of the resin film 10. After that, the via holes 13 are filled with paste-like metal materials 14. The paste-like metal material 14 is a paste-like mixture of metal powder and an organic solvent or the like. Consequently, the metal material 14 is linked to the land electrode 11. The metal material 14 is a via-forming material for forming the via 12. Therefore, the metal material 14 composes the interlayer connection material.

Next, as illustrated in FIG. 2B, a lamination process for laminating the plurality of resin films 10 to form a laminated body 20 is performed. In the lamination process, basically, a surface 10a of one resin film 10 provided with the land electrodes 11 is arranged to face a surface 10b of another resin film 10 provided with no land electrodes 11. Then, two resin films 101 and 102 located in the middle of the plurality of resin films 10 in the lamination direction are arranged such that the surfaces 10b with no land electrodes 11 face each other. Consequently, the plurality of land electrodes 11 and the plurality of metal materials 14 are continuously arranged in the lamination direction of the plurality of resin films 10 to form a continuous structure 21, and the laminated body 20 including the continuous structures 21 is formed. The continuous structure 21 according to the present embodiment is formed by the plurality of land electrodes 11 located on the first surface 1a, on the second surface 1b, and between the first surface 1a and the second surface 1b of the multilayer substrate 1. In the laminated body 20, there is a gap 22 in a region free from land electrodes 11 between the laminated resin films 10, and a plurality of the gaps 22 is present in the lamination direction (that is, Z direction in FIG. 2A).

At this time, at least two or more land electrodes 11 that configure one continuous structure 21 are displaced from each other as viewed in the lamination direction. For example, in FIG. 2B, the second and third land electrodes 11 from the top are displaced from the first land electrode 11 from the top. Furthermore, the sixth and seventh land electrodes 11 from the top are displaced from both the first and second land electrodes 11 from the top. Similarly, at least two or more metal materials 14 that configure one continuous structure 21 are displaced from each other as viewed in the lamination direction. The sentence “two metal materials 14 are displaced from each other” means that the positions of opposite ends of one metal material 14 are different from those of the other metal material 14 in the direction along the surface of the multilayer substrate 1. Consequently, at least two or more of the plurality of gaps present in the laminated body in the lamination direction are also displaced from each other as viewed in the lamination direction.

Next, as illustrated in FIG. 2C, a heating pressing process for heating and pressing the laminated body 20 in the lamination direction is performed. The heating temperature at this time is a temperature at which the thermoplastic resin that composes the resin films 10 is softened to flow. In this process, the thermoplastic resin flows to fill the gap 22 in the laminated body 20. Then, the resin films 10 are bonded together and integrated. At the same time, the metal materials 14 are sintered by heat and become the vias 12. Consequently, the plurality of land electrodes 11 disposed in the lamination direction is electrically connected to one another through the plurality of vias 12. In this manner, the multilayer substrate 1 illustrated in FIG. 1 is manufactured.

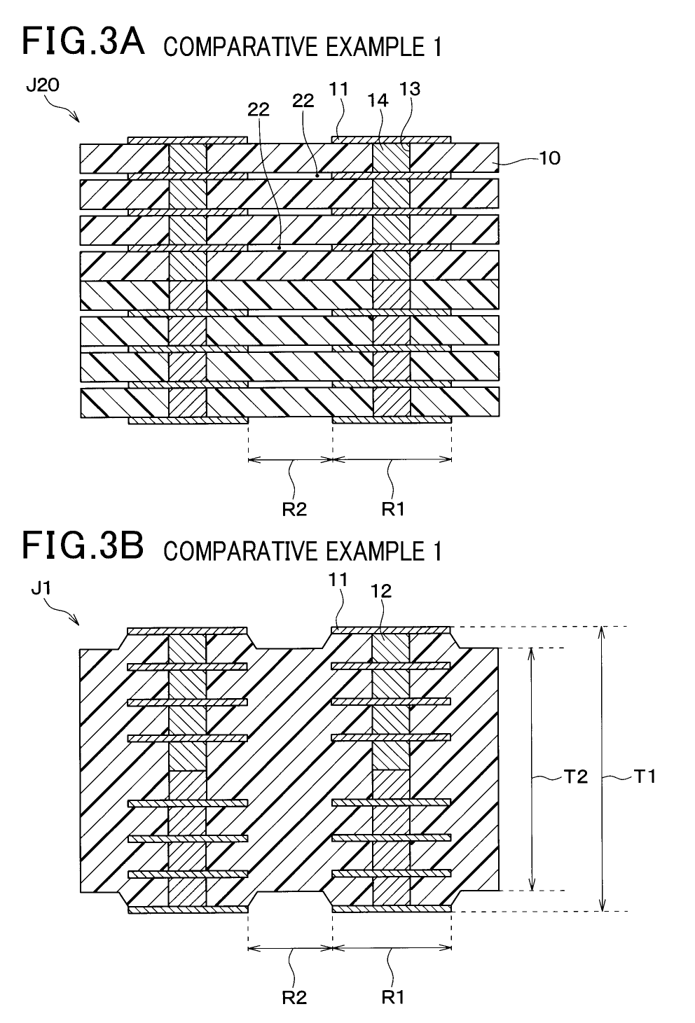

In the following paragraphs, the method for manufacturing the multilayer substrate 1 according to the present embodiment is compared with a method for manufacturing a multilayer substrate J1 according to Comparative Example 1 illustrated in FIGS. 3A and 3B.

In Comparative Example 1, as illustrated in FIG. 3A, before a laminated body J20 is subjected to the heating pressing process, land electrodes 11 having the same circular shape are arranged at the same position as viewed in the lamination direction. Consequently, all of a plurality of gaps 22 disposed in the lamination direction are located at the same position as viewed in the lamination direction. In the direction vertical to the lamination direction, the laminated body 20 has a region R1 provided with the land electrodes 11 and a resin region R2 free from land electrodes 11 and including the gaps 22.

Therefore, as illustrated in FIG. 3B, after the heating pressing process, the thickness T2 of the resin region R2 of the multilayer substrate J1 free from land electrodes 11 is less than the thickness T1 of the region R1 of the multilayer substrate J1 provided with the land electrodes 11. Thus, the method for manufacturing the multilayer substrate J1 according to Comparative Example 1 causes a deterioration in the planarity of the multilayer substrate 1.

In contrast, in the present embodiment, before the laminated body 20 is subjected to the heating pressing process, at least two or more land electrodes 11 are displaced from each other as viewed in the lamination direction. Consequently, at least two or more gaps 22 disposed in the lamination direction are displaced from each other as viewed in the lamination direction. More specifically, each land electrode 11 is arranged at any one of three different types of arrangement places. Each gap 22 is arranged at any one of three different types of arrangement places.

Therefore, the thickness T3 of the multilayer substrate 1 subjected to the heating pressing process can be much more uniform than that in Comparative Example 1. Thus, according to the present embodiment, the planarity of the multilayer substrate 1 can be improved.

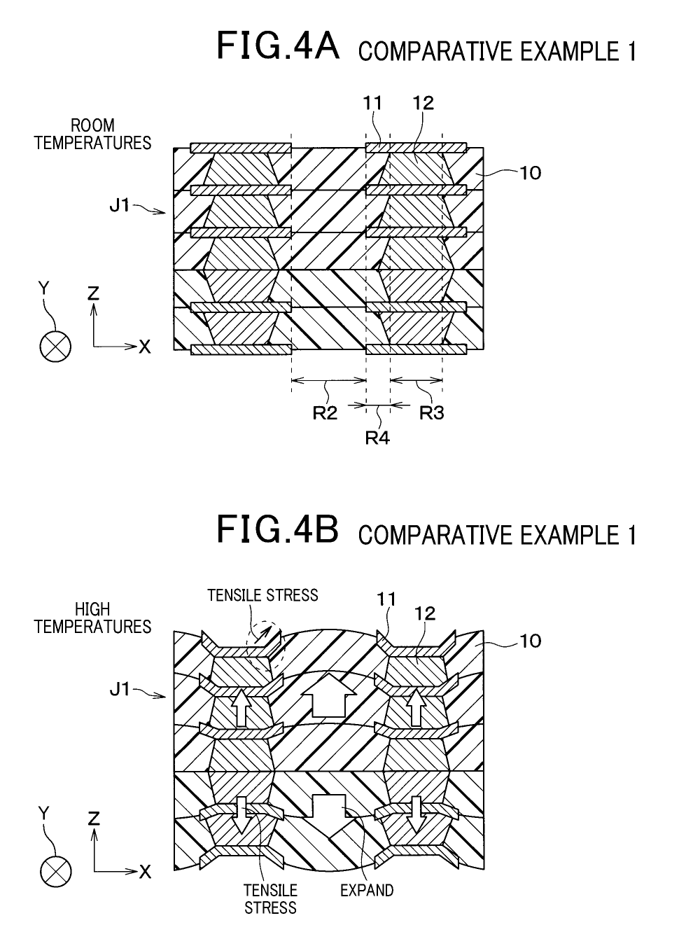

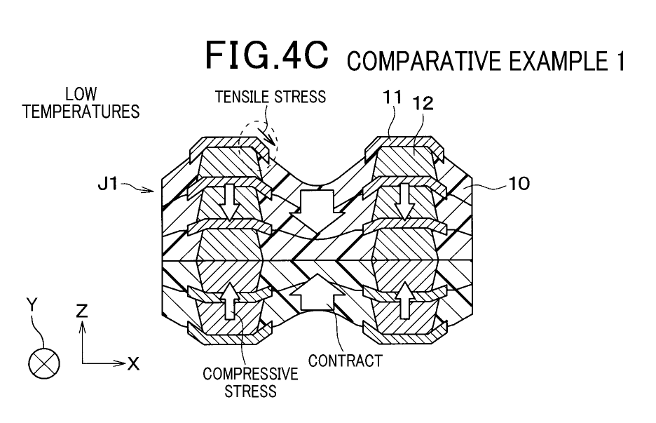

As illustrated in FIG. 4A, the multilayer substrate J1 manufactured using the manufacturing method according to Comparative Example 1 has the resin region R2 having only resin in the Z direction, a metal region R3 having only metal in the Z direction, and a mixed region R4 having both metal and resin in the Z direction. In other words, in the multilayer substrate J1, the region between any two land electrodes 11 adjacent to each other in the X direction, is a region having only resin.

This causes the problem of damage to the inside of the multilayer substrate J1 due to thermal stress. More specifically, as illustrated in FIG. 4B, the multilayer substrate J1 expands if the temperature is higher than ordinary temperatures. In this regard, tensile stress is applied to the vias 12 in the Z direction since the materials that configure the resin region R2, the metal region R3, and the mixed region R4 have different thermal expansion coefficients. In addition, as illustrated in FIG. 4C, the multilayer substrate J1 contracts if the temperature is lower than ordinary temperatures. At this time, compressive stress is applied to the vias 12 in the Z direction since the materials that configure the resin region R2, the metal region R3, and the mixed region R4 have different thermal expansion coefficients. These tensile stress and compressive stress cause tensile stress on the vias 12, whereby cracks occur in the vias 12.

In contrast, the multilayer substrate 1 according to the present embodiment is free from regions having only resin in the Z direction and having only metal in the Z direction. In other words, in the multilayer substrate 1, the region between any two land electrodes 11 adjacent to each other in the X direction is a mixed region having both metal and resin.

Therefore, the stress resulting from the difference in the thermal expansion coefficients between metal and resin can be dispersed. Consequently, the occurrence of damage to the multilayer substrate 1 due to thermal stress can be prevented. Thus, the reliability of the multilayer substrate 1 can be improved.

In the present embodiment, before the laminated body 20 is subjected to the heating pressing process, the plurality of land electrodes 11 that configures one continuous structure 21 is displaced from one another so that the laminated body 20 is completely free from the resin region R2 having only resin in the Z direction. However, the laminated body 20 does not necessarily have to be completely free from the resin region R2. The plurality of land electrodes 11 is displaced from one another to make the resin region R2 smaller than that of the laminated body J20 of Comparative Example 1. Consequently, the planarity of the multilayer substrate 1 can be improved to a greater extent than in Comparative Example 1. However, it is preferable that the multilayer substrate 1 be completely free from the resin region R2 having only resin in the Z direction in terms of further improvement in the planarity of the multilayer substrate 1.

In the lamination process according to the present embodiment, the two resin films 101 and 102 located in the middle of the plurality of resin films 10 in the lamination direction are arranged such that the surfaces 10b provided with no land electrodes 11 face each other. Alternatively, two resin films 10 located at other positions, not in the middle of the plurality of resin films 10 in the lamination direction, may be arranged such that the surfaces 10b provided with no land electrodes 11 face each other.

### Second Embodiment

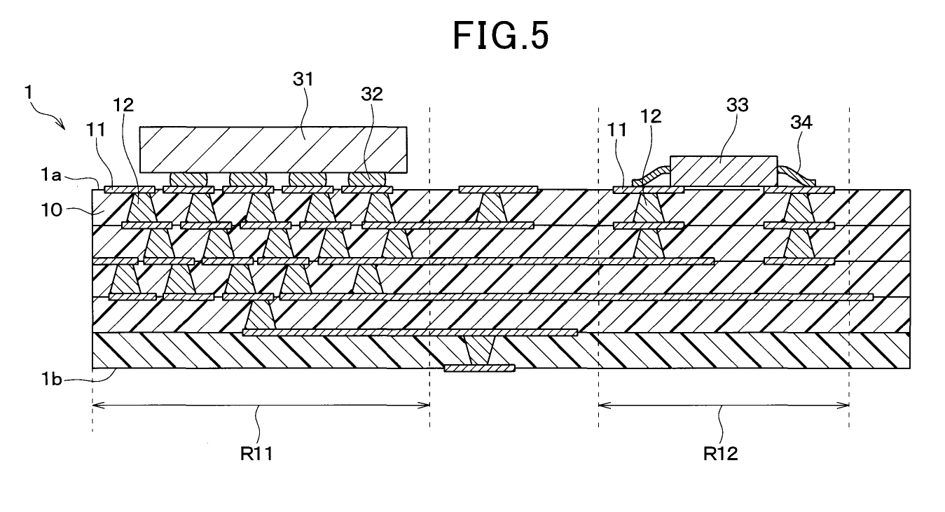

As illustrated in FIG. 5, a multilayer substrate 1 according to the present embodiment includes a first region R11 including land electrodes 11 and vias 12 displaced from one another and a second region R12 including land electrodes 11 and vias 12 arranged at the same position.

The structure of the first region R11 is similar to that of the multilayer substrate 1 according to the first embodiment. An IC chip 31 is mounted on a first surface la of the multilayer substrate 1 in the first region R11. The IC chip 31 is connected to the land electrodes 11 by balls of solder 32.

The structure of the second region R12 is similar to that of the multilayer substrate J1 according to Comparative Example 1 described in the first embodiment. An IC chip 33 is mounted on the first surface 1a of the multilayer substrate 1 in the second region R12. The IC chip 33 is connected to the land electrodes 11 by wires 34.

In the present embodiment, the first region R11 requires higher planarity than the second region R12. In the first region R11, therefore, the land electrodes 11 and the vias 12 are displaced from one another as in the first embodiment. To be more specific, before a laminated body 20 is subjected to the heating pressing process, at least two or more land electrodes 11 are displaced from each other, and at least two or more metal materials 14 are displaced from each other. Consequently, the planarity of the first region R11 can be improved.

### Third Embodiment

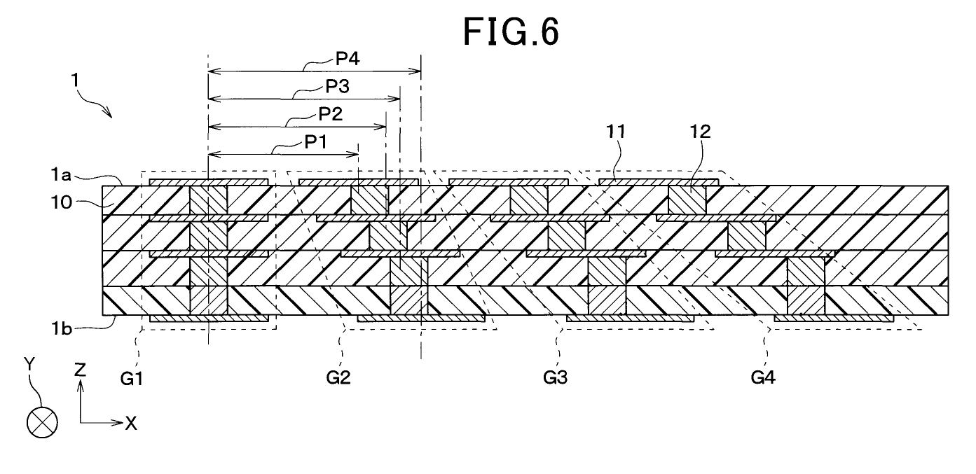

As illustrated in FIG. 6, a multilayer substrate 1 according to the present embodiment has a plurality of groups of land electrodes G1, G2, G3, and G4 configuring a plurality of land electrodes 11 disposed in the Z direction that are electrically connected. The plurality of groups of land electrodes G1, G2, G3, and G4 are arranged side by side in a direction along the surface of the multilayer substrate 1 (for example, X direction). The plurality of groups of land electrodes G1, G2, G3, and G4 are arranged such that the pitch P1 between the land electrodes 11 located on a first surface la of the multilayer substrate 1 is different from the pitch P4 between the land electrodes 11 located on a second surface 1b of the multilayer substrate 1. The pitch between the land electrodes 11 as used herein means the distance between the centers of the land electrodes 11 adjacent to each other in the direction along the surface of the multilayer substrate 1.

More specifically, the pitches P1 to P4 between the land electrodes 11 on the respective layers, that is, the pitch P1 between the land electrodes 11 on the first layer from the first surface 1a, the pitch P2 between the land electrodes 11 on the second layer, the pitch P3 between the land electrodes 11 on the third layer, and the pitch P4 between the land electrodes 11 on the fourth layer, satisfy the relation P1<P2<P3<P4. Thus, the land electrodes 11 in each of the groups of land electrodes G1 to G4 are displaced from one another such that the pitches P1 to P4 between the land electrodes 11 on the respective layers are larger on the layers closer to the second surface 1b and smaller on the layers closer to the first surface la. Consequently, the pitch P4 between the land electrodes 11 on the second surface 1b is larger than the pitch P1 between the land electrodes 11 on the first surface 1a.

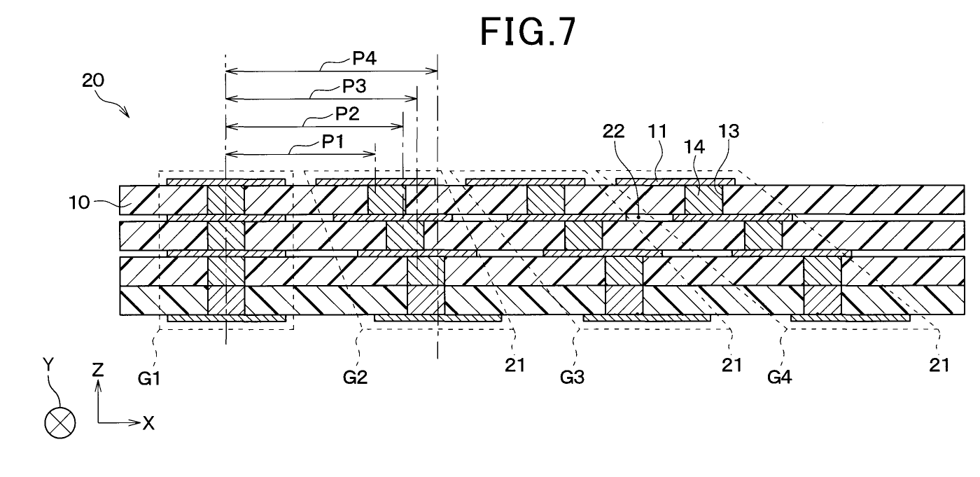

Such a multilayer substrate 1 is manufactured in the following manner as illustrated in FIG. 7. Before a laminated body 20 is subjected to the heating pressing process, the plurality of land electrodes 11 is displaced from one another such that the distances P1 to P4 between one set of land electrodes 11 located at the same position in the lamination direction and another set of land electrodes 11 located at the same position in the lamination direction are smaller on the layers closer to one side and larger on the layers closer to the other side in the lamination direction.

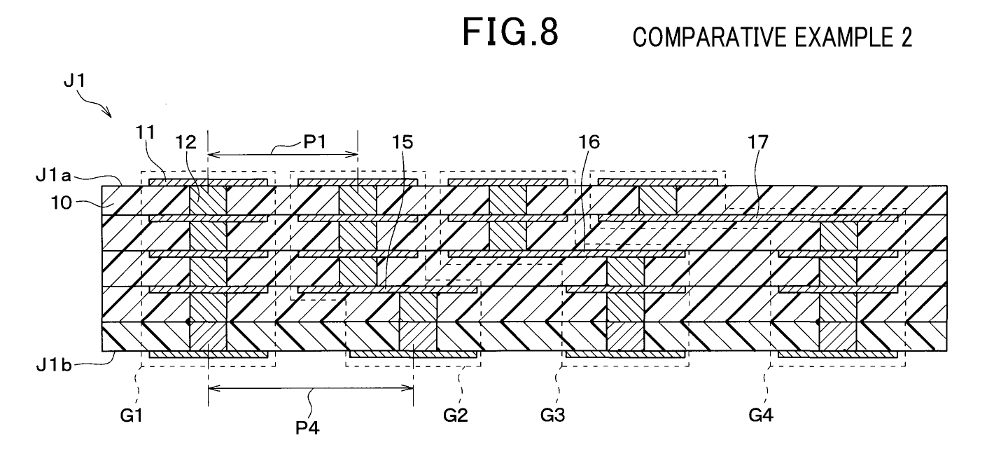

In the following paragraphs, the multilayer substrate 1 according to the present embodiment is compared with a multilayer substrate J1 according to Comparative Example 2 illustrated in FIG. 8. In the structure employed in Comparative Example 2, land electrodes 11 are basically located at the same position as viewed in the lamination direction while the pitch P1 between the land electrodes 11 on a first surface J1a of the multilayer substrate J1 is different from the pitch P4 between the land electrodes 11 on a second surface J1b of the multilayer substrate J1 as in the present embodiment. In this case, layers of lead-out wiring 15, 16, and 17 are respectively required by the groups of land electrodes G2, G3, and G4 whose land electrodes 11 need to be moved. Therefore, Comparative Example 2 illustrated in FIG. 8 requires three conductor layers inside the multilayer substrate J1.

In contrast, in the present embodiment, conversion of pitches between the land electrodes 11 is enabled since the land electrodes 11 are displaced from one another as viewed in the lamination direction such that the pitches P1 to P4 between the land electrodes 11 are stepwisely increased from P1 to P4. Since the amount of conversion between the land electrodes 11 is dispersed to all the conductor layers in this manner, the groups of land electrodes G2, G3, and G4 do not need to respectively include the layers of lead-out wiring 15, 16, and 17 like in Comparative Example 2. The present embodiment only requires two conductor layers, that is, land electrodes 11, inside the multilayer substrate 1. Therefore, according to the present embodiment, the total number of conductor layers of the multilayer substrate 1 can be reduced.

### Fourth Embodiment

The present embodiment is a partial modification of the method for manufacturing the multilayer substrate 1 according to the first embodiment.

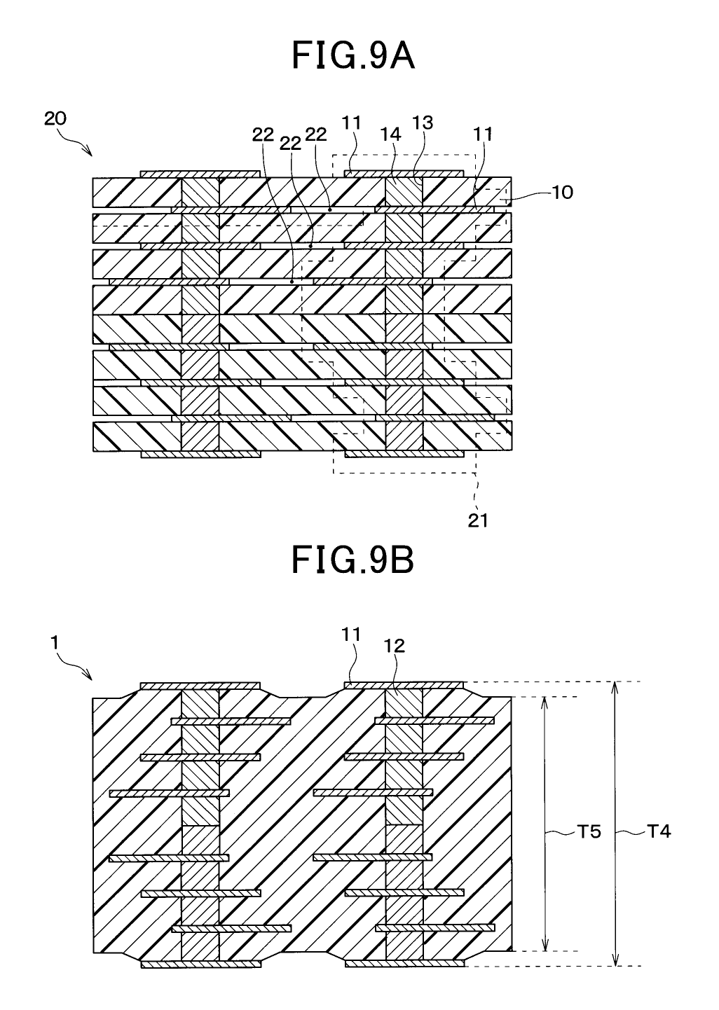

As illustrated in FIG. 9A, in the lamination process according to the present embodiment, a laminated body 20 having land electrodes 11 and metal materials 14 is formed such that only the land electrodes 11 are displaced from one another. The inside of the laminated body 20 is similar to that in the first embodiment such that a plurality of gaps 22 in the lamination direction is displaced from one another as viewed in the lamination direction.

Therefore, as illustrated in FIG. 9B, the difference between the thickness T4 and the thickness T5 of the multilayer substrate 1 subjected to the heating pressing process can be smaller than that in Comparative Example 1. In other words, the thickness of the multilayer substrate 1 subjected to the heating pressing process can be much more uniform in the present embodiment than in Comparative Example 1.

### Fifth Embodiment

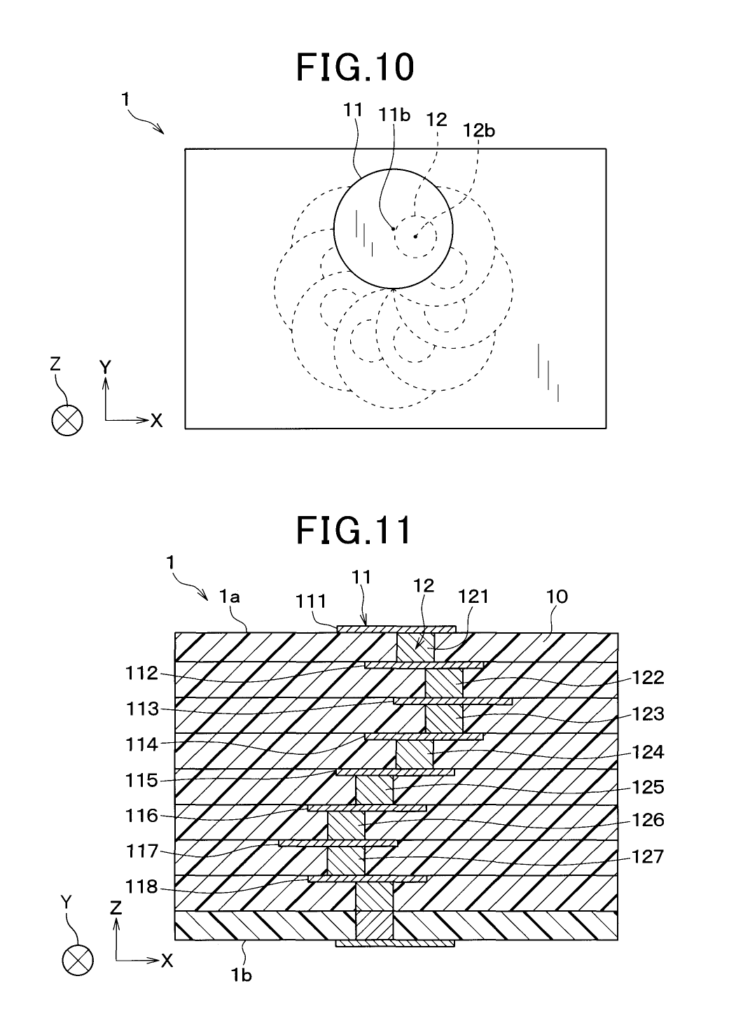

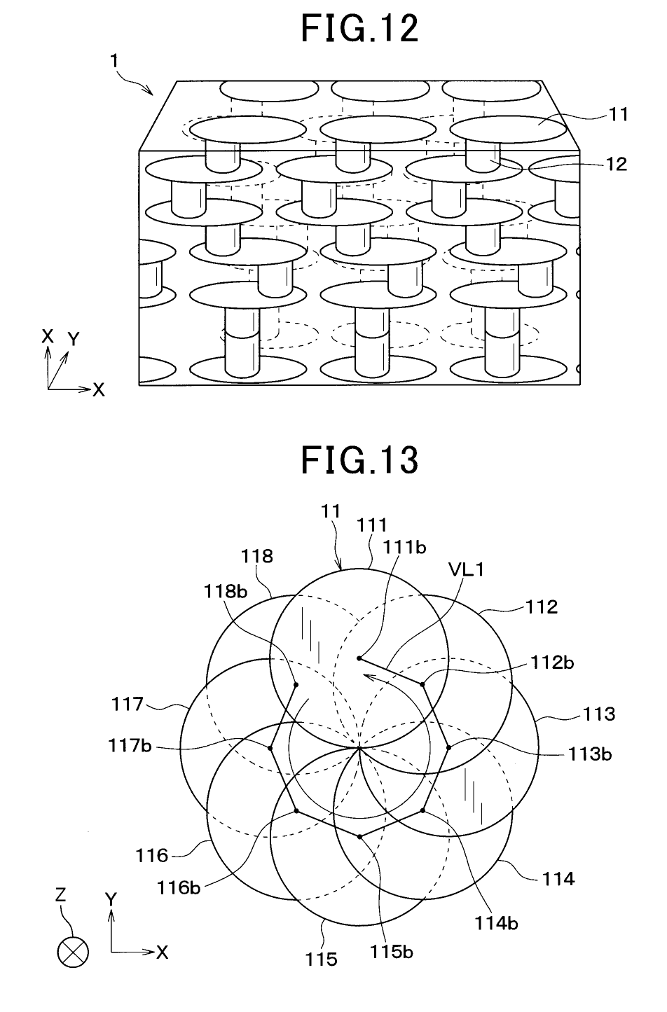

As illustrated in FIGS. 10, 11, and 12, a multilayer substrate 1 according to the present embodiment includes a plurality of land electrodes 11 electrically connected and spirally arranged. A plurality of vias 12 electrically connecting the plurality of land electrodes 11 is also spirally arranged.

As used herein, the sentence “a plurality of land electrodes 11 is spirally arranged” means that the plurality of land electrodes 11 is arranged such that a virtual line VL1 sequentially connecting centers 11b of the land electrodes 11 in the lamination direction forms a spiral line as illustrated in FIGS. 11 and 13. As illustrated in FIG. 13, when land electrodes 111 to 118 of FIG. 11 are illustrated on the same plane, the virtual line VL1 sequentially connecting centers 111b to 118b of the respective land electrodes 111 to 118 in the Z direction forms a peripheral line (for example, circumferential line).

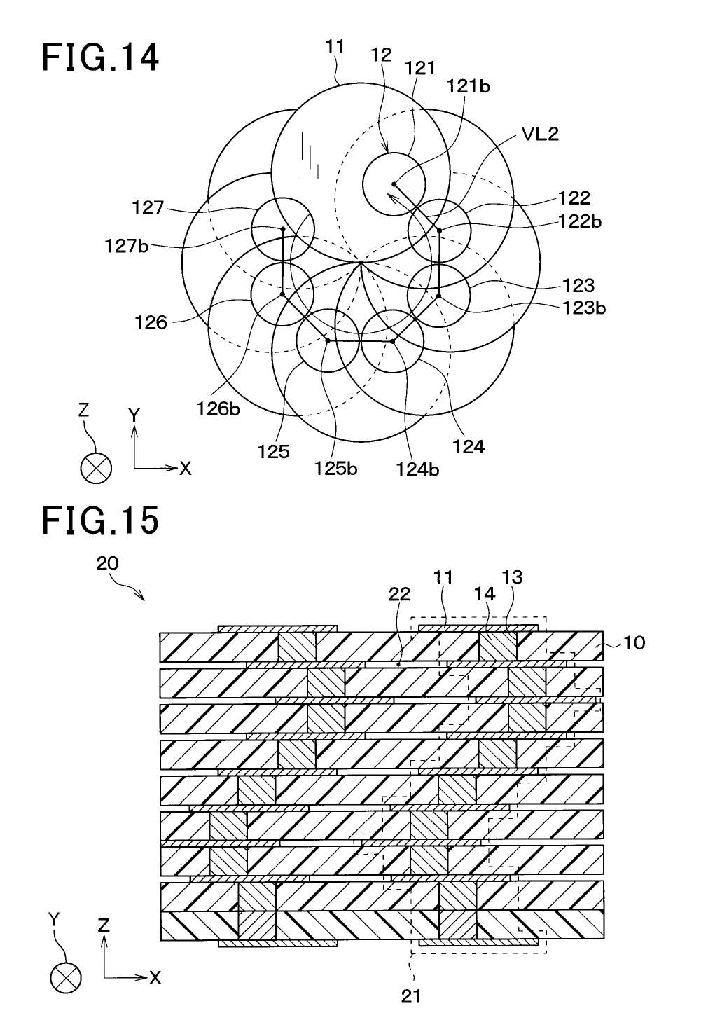

Similarly, the sentence “a plurality of vias 12 is spirally arranged” means that the plurality of vias 12 is arranged such that a virtual line VL2 sequentially connecting centers 12b of the vias 12 in the lamination direction forms a spiral line as illustrated in FIGS. 11 and 14. As illustrated in FIG. 14, when vias 121 to 127 of FIG. 11 are illustrated on the same plane, the virtual line VL2 sequentially connecting centers 121b to 127b of the respective vias 121 to 127 in the Z direction forms a peripheral line (for example, circumferential line).

As illustrated in FIG. 14, the position of the center 12b of the via 12 is different from the position of the center 11b of the land electrode 11 connected to the via 12. The via 12 is arranged in a region where the two land electrodes 11 connected thereto overlap each other as viewed in the Z direction.

Next, a method for manufacturing the multilayer substrate 1 according to the present embodiment will be described. The lamination process of the method for manufacturing the multilayer substrate 1 according to the first embodiment is changed in the following manner. Specifically, as illustrated in FIG. 15, a laminated body 20 is formed such that all of a plurality of land electrodes 11 that configures a continuous structure 21 are spirally arranged, and all of a plurality of metal materials 14 that configures the continuous structure 21 are spirally arranged. In this manner, the multilayer substrate 1 having the above structure is manufactured.

As described above, in the present embodiment, the plurality of land electrodes 11 is spirally arranged, and thus the plurality of land electrodes 11 is displaced from one another in both the X and Y directions. Therefore, a plurality of gaps 22 in the laminated body 20 is displaced from one another in both the X and Y directions, so that the effect similar to that of the first embodiment can be obtained.

Furthermore, the following effect can be obtained by the present embodiment. Specifically, in a case where the plurality of land electrodes 11 is spirally arranged as in the present embodiment, the positions of the land electrodes 11 may be changed little by little from those in the conventional structure having a plurality of land electrodes 11 that is linearly arranged. Therefore, the multilayer substrate 1 according to the present embodiment can be designed with reference to the conventional structure including a plurality of land electrodes 11 linearly arranged.

### Sixth Embodiment

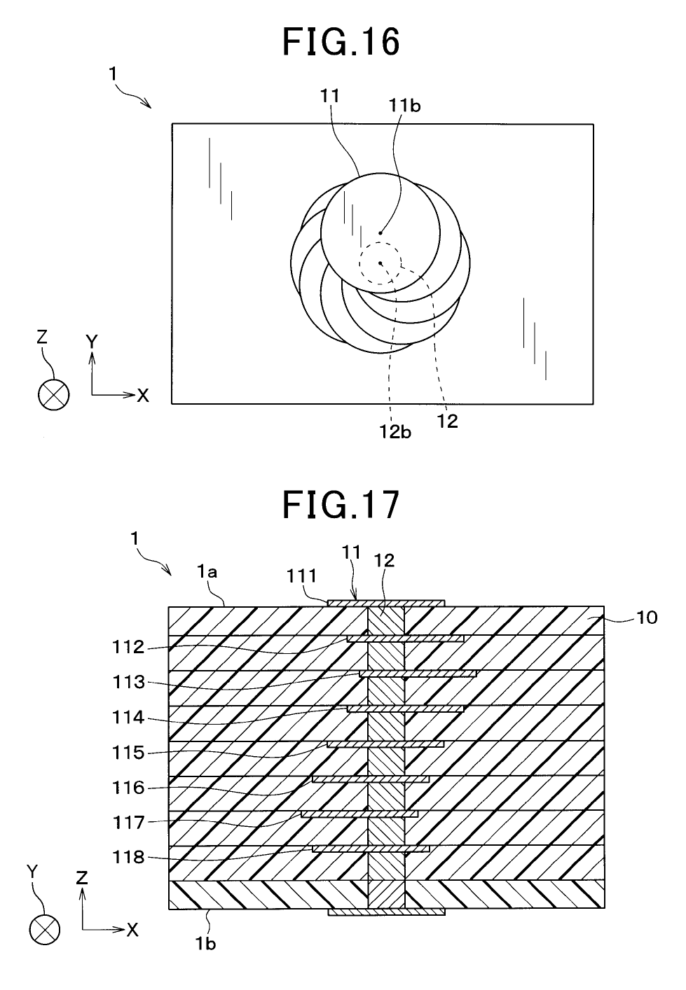

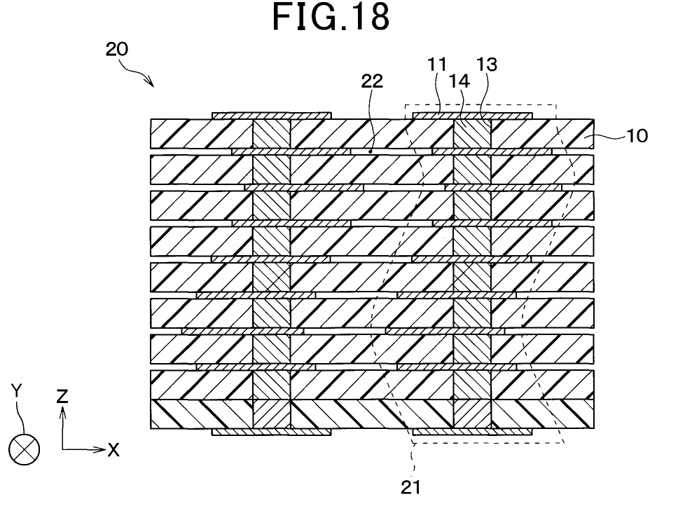

As illustrated in FIGS. 16 and 17, a multilayer substrate 1 according to the present embodiment includes a plurality of land electrodes 11 and a plurality of vias 12 that are electrically connected, with only the land electrodes 11 spirally arranged. The plurality of vias 12 is linearly arranged.

As illustrated in FIG. 18, in the lamination process according to the present embodiment, a laminated body 20 is formed such that all of a plurality of land electrodes 11 that configures a continuous structure 21 are spirally arranged, and all of a plurality of metal materials 14 that configures the continuous structure 21 are linearly arranged. In this manner, the multilayer substrate 1 having the above structure is manufactured.

Since the land electrodes 11 are spirally arranged, the effect similar to that of the fifth embodiment can be achieved in the present embodiment as well.

The land electrodes 11 can be displaced from one another to a greater extent in a case where the plurality of metal materials 14 (namely, the plurality of vias 12) is spirally arranged than in a case where the plurality of metal materials 14 is linearly arranged. Therefore, the fifth embodiment is preferable to the sixth embodiment.

### Other Embodiments

The present invention is not limited to the above embodiments and can be appropriately changed as follows.

(1) In the first embodiment, the land electrodes 11 are not displaced in the Y direction but displaced only in the X direction. Alternatively, the land electrodes 11 may be displaced in both the X and Y directions. In this regard, the plurality of land electrodes 11 is not necessarily spirally arranged but may be arranged in a different manner.

(2) In the first embodiment, the plurality of land electrodes 11 that configures the continuous structure 21 is arranged at the three types of positions. However, the plurality of land electrodes 11 may be arranged at two types of positions or four types of positions. However, the plurality of land electrodes 11 is preferably arranged at three or more types of positions so that the plurality of gaps 22 in the laminated body 20 is dispersed in a direction vertical to the lamination direction.

(3) In each of the above embodiments, the planar shape of the land electrode 11 is a circular shape. Alternatively, the planar shape of the land electrode 11 may be another shape such as a polygonal shape. In a case where the planar shape of the land electrode 11 is neither a circular shape nor a regular polygonal shape, the center 11b of the land electrode 11 indicates the barycentric position of a predetermined planar shape.

(4) In each of the above embodiments, the resin film 10 includes a thermoplastic resin. Alternatively, the resin film 10 may include a resin material other than the thermoplastic resin. The resin material only needs to be softened to flow in the heating pressing process. The resin film 10 may be made only by a resin material or may contain not only a resin material but also other materials. In short, the resin film 10 may be made from at least a resin material.

(5) The above embodiments are not unrelated to one another but can be appropriately combined unless it is clearly impossible to combine them. Needless to say, components that constitute each of the above embodiments are not necessarily essential unless it is specified that the components are essential and unless it is considered that the components are clearly essential in principle.

### REFERENCE SIGNS LIST

10 . . . resin film
11 . . . land electrode
13 . . . via hole (through hole)
14 . . . metal material
20 . . . laminated body
21 . . . continuous structure
22 . . . gap

What is claimed is:

1. A method for manufacturing a multilayer substrate, the method comprising:
a preparation process of preparing a plurality of film-like insulating substrates including at least a resin material, the insulating substrates each including: a land electrode formed on a surface of the insulating substrate and having a predetermined planar shape; and an interlayer connection material filled into a through hole penetrating the insulating substrate in a thickness direction and linked to the land electrode;
a lamination process of laminating the plurality of insulating substrates to form a laminated body including: a continuous structure including a plurality of the land electrodes and a plurality of the interlayer connection materials continuously arranged in a lamination direction of the insulating substrates; and a gap generated in a region free from the land electrodes between the laminated insulating substrates, a plurality of the gaps being present in the lamination direction; and
a heating pressing process of heating and pressing the laminated body in the lamination direction to cause the plurality of insulating substrates to flow and fill the gaps, wherein,
the lamination process includes forming the laminated body in which at least two or more of the land electrodes that configure the continuous structure are displaced from each other as viewed in the lamination direction, and at least two or more of the gaps present in the lamination direction are displaced from each other as viewed in the lamination direction.

2. The method for manufacturing a multilayer substrate according to claim 1, wherein,
the lamination process includes forming the laminated body in which the plurality of land electrodes that configures the continuous structure is spirally arranged.

3. The method for manufacturing a multilayer substrate according to claim 1, wherein,
the lamination process further includes forming the laminated body in which at least two or more of the interlayer connection materials that configure the continuous structure are displaced from each other as viewed in the lamination direction.

4. The method for manufacturing a multilayer substrate according to claim 1, wherein,
the lamination process includes forming the laminated body in which the plurality of land electrodes that configures the continuous structure is spirally arranged, and the plurality of interlayer connection materials that configures the continuous structure is spirally arranged.

5. A multilayer substrate comprising:
a plurality of film-like insulating substrates including at least a resin material and being laminated;
a plurality of land electrodes arranged on a surface of each of the plurality of insulating substrates and having a predetermined planar shape; and
a plurality of interlayer connection materials provided in each of the plurality of insulating substrates and connected to the land electrodes, wherein,
the plurality of land electrodes and the plurality of interlayer connection materials are continuously arranged in a lamination direction of the insulating substrates to form a continuous structure, and
at least two or more of the land electrodes that configure the continuous structure are displaced from each other as viewed in the lamination direction.

6. The multilayer substrate according to claim 5, wherein,
the plurality of land electrodes that configures the continuous structure is spirally arranged.

7. The multilayer substrate according to claim 5, wherein,
at least two or more of the interlayer connection materials that configure the continuous structure are displaced from each other as viewed in the lamination direction.

8. The multilayer substrate according to claim 5, wherein,
the plurality of land electrodes that configures the continuous structure is spirally arranged, and the plurality of interlayer connection materials that configures the continuous structure is spirally arranged.
